(19) United States
(12) Patent Application Publication
(10) Pub. No.: US 2007/0161259 A1
(43) Pub. Date: Jul. 12, 2007

(54) Two Dimensional Nanostructure Fabrication Method and Two Dimensional Nanostructure Fabricated Therefrom

(75) Inventors: Se-ahn Song, Seoul (KR); Alexander V. Latyshev, Novosibirsk (RU); Ludmila I. Fedina, Novosibirsk (RU); Anton K. Gutakovskii, Novosibirsk (RU); Sergey S. Kosolobov, Novosibirsk (RU)

Correspondence Address: CANTOR COLBURN, LLP, 55 GRIFFIN ROAD SOUTH, BLOOMFIELD, CT, 06002, US

(73) Assignee: SAMSUNG ELECTRONICS CO. LTD., Suwon-si (KR)

(21) Appl. No.: 11/548,442

(22) Filed: Oct. 11, 2006

(30) Foreign Application Priority Data
Jan. 6, 2006 (KR) 2006-0002011

(51) Int. Cl. H01L 21/31; H01L 21/469

(52) U.S. Cl. 438/787

(57) ABSTRACT

Disclosed herein is a method of fabricating a two dimensional (2D) nanostructure. The method includes heating a substrate within a vacuum chamber, injecting a metallic material into the vacuum chamber, adsorbing the metallic material on a surface of the substrate, and cooling the substrate to fabricate the 2D nanostructure on the surface of the substrate. The 2D nanostructures can be fabricated as monolayers.

### CROSS-REFERENCE TO RELATED APPLICATIONS

This application claims priority to Korean Patent Application No. 2006-2011, filed on Jan. 6, 2006 in the Korean Intellectual Property Office, and all the benefits accruing therefrom under 35 U.S.C. § 119, the disclosure of which is incorporated herein by reference in its entirety.

### BACKGROUND OF THE INVENTION

1. Field of the Invention

The present invention generally relates to a method of making a two-dimension (2D) nanostructure and the 2D nanostructure fabricated therefrom. More particularly, the present invention relates to a method of making a 2D nanostructure by adsorbing a metallic material on a substrate, and the 2D nanostructure fabricated therefrom.

2. Description of the Related Art

With the epoch-making miniaturization of electronic products, methods of making nano-scale structures are of huge interest. Nano-scale structures, that is, nanostructures find application in quantum well lasers, photoluminescence, electrometers, nanocrystal memory, and the like. Methods for making nanostructures on substrates can primarily be classified into two categories: lithographic processes, and self-organization or self-assembly processes.

Lithographic processes have limitations as far as minimizing the size of the nanostructure and can also suffer from low resolution. Hence, it can be hard to fabricate an elaborate and complicated nanostructure on a substrate using lithographic processes.

With respect to self-assembly processes, the low density of the islands formed by aggregation of atoms on the substrate surface is problematic owing to the considerable distance that the atoms on the substrate surface travel at high temperature. In contrast, at low temperatures, a three-dimensional (3D) nanostructure is likely to be fabricated owing to a high rate of stacking. The 2D nanostructure represents a nanostructure in the form of a thin film of which the height or thickness is negligible, whereas the 3D nanostructure represents a conglomerate nanostructure with a measurable height or thickness.

There accordingly, remains a need in the art for improved methods of making 2D nanostructures with increased utility.

### BRIEF SUMMARY OF THE INVENTION

The present invention addresses the above-mentioned and other problems and disadvantages occurring in the art, and an aspect of the present invention includes providing a method of fabricating a 2D nanostructure from internal elements of a substrate by heating the substrate in a vacuum chamber, injecting and adsorbing a metallic material, and producing the nanostructure.

According to another aspect of the present invention, a method for fabricating a 2D nanostructure using a vacuum chamber, includes heating a substrate within the vacuum chamber, injecting a metallic material into the vacuum chamber and adsorbing the metallic material on the substrate; and cooling the substrate to fabricate the 2D nanostructure on a surface of the substrate.

In accordance with another exemplary embodiment, the metallic material diffuses into the substrate, substitutes for an internal element of the substrate, wherein the internal element has substantially the same volume as the metallic material, and shifts the internal element to the surface of the substrate.

In accordance with another exemplary embodiment, the shifted internal element binds to the surface of the substrate during the cooling.

In accordance with another exemplary embodiment, the substrate has a step formed on the surface during the heating.

In accordance with another exemplary embodiment, the 2D nanostructure may include a wire shaped nanostructure fabricated along a step or an island shaped nanostructure fabricated on a non-step area.

In accordance with another exemplary embodiment, the substrate may be a crystalline silicon substrate.

In accordance with another exemplary embodiment, the metallic material may be at least one of gold, silver, and tin.

In accordance with another exemplary embodiment, a temperature in the vacuum chamber is about 20 to about 1350 degrees Celsius during the heating and absorbing.

In accordance with another exemplary embodiment, the metallic material adsorbs on the substrate at a rate of about 0.001 to about 1.000 monolayers per minute.

In accordance with another exemplary embodiment, the metallic material adsorbs on the substrate for about 1 to about 1000 seconds.

In accordance with another exemplary embodiment, a pressure of the vacuum chamber is about 10⁻⁶ to about 10⁻¹¹ Torr.

In accordance with another exemplary embodiment, a size of the 2D nanostructure may be about 10to about 1300 nanometers, and a surface density of the 2D nanostructure may be greater than about 10¹⁰ per cubic centimeter.

In accordance with another aspect of the present invention, a 2D nanostructure is fabricated on a surface of a substrate by heating the substrate within the vacuum chamber, injecting a metallic material into the vacuum chamber and adsorbing the metallic material on the surface of the substrate; and cooling the substrate.

In accordance with an exemplary embodiment, the substrate has a step on the surface.

In accordance with another exemplary embodiment, the 2D nanostructure includes a wire shaped nanostructure along a step or an island shaped nanostructure on a non-step area.

In accordance with another exemplary embodiment, the substrate may be a crystalline silicon substrate.

### BRIEF DESCRIPTION OF THE DRAWINGS

The above and/or other aspects of the present invention will become more apparent and more readily appreciated from the following detailed description taken in conjunction with the accompanying drawings, in which:

FIGS. 1A through 1E are schematic illustrations of a method of making a 2D nanostructure according to an exemplary embodiment of the present invention;

FIG. 2A is an exemplary atomic force microscope image of a surface of a substrate before fabrication of the 2D nanostructure;

FIG. 2B is an exemplary atomic force microscope image of the surface of the substrate after fabrication of the 2D nanostructure;

FIG. 3 is another exemplary atomic force microscope image of the surface of the substrate after fabrication of the 2D nanostructure;

FIG. 4 is a graph illustrating the size distribution of 2D nanostructures fabricated on the surface of the substrate according to an exemplary embodiment;

FIGS. 5A and 5B are schematic illustrations of an exemplary embodiment of a connection between chips using the 2D nanostructure according to the present invention;

FIGS. 6A through 6C are schematic illustrations of the oxidization over time of a conventional substrate; and

FIGS. 7A through 7C are schematic illustrations of the oxidization over time of the substrate on which the 2D nanostructure is fabricated according to an exemplary embodiment of the present invention.

### DETAILED DESCRIPTION OF THE INVENTION

The present invention will now be described more fully hereinafter with reference to the accompanying drawings, in which exemplary embodiments of the present invention are shown. This invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

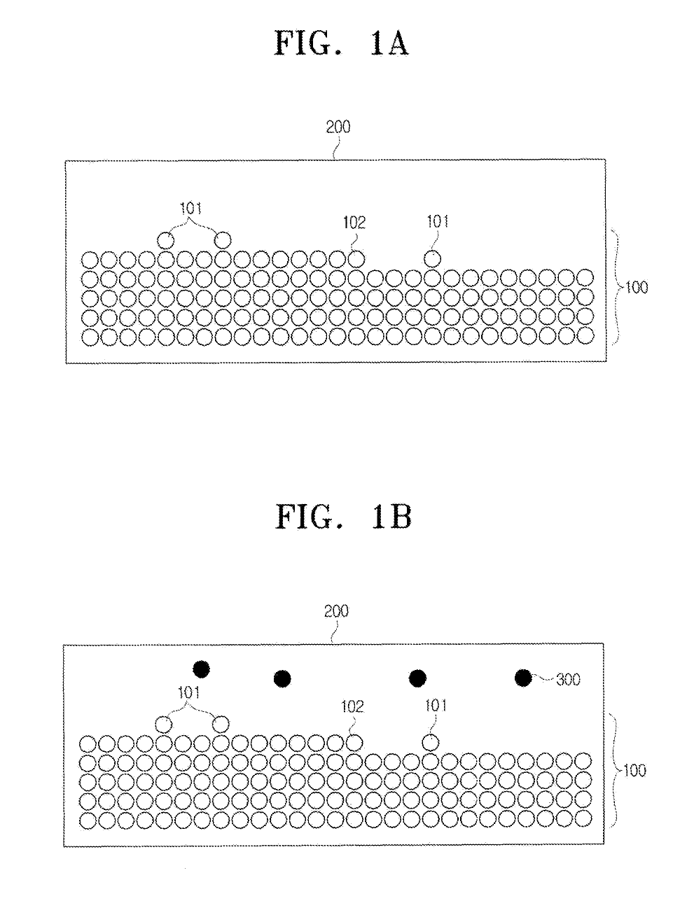

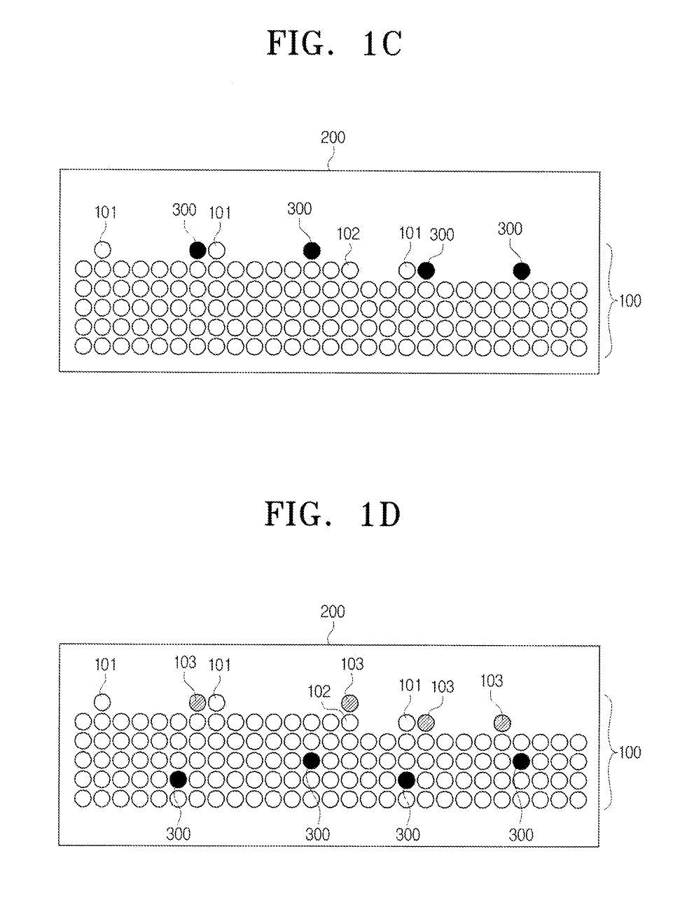

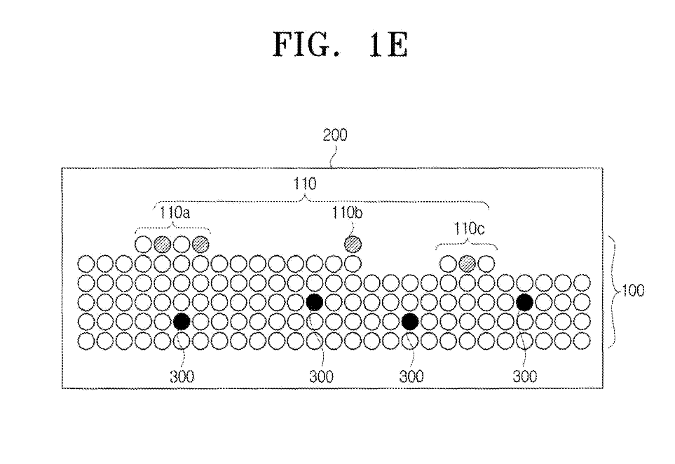

FIGS. 1A through 1E schematically illustrate an exemplary embodiment of a method of making a 2D nanostructure according to the present invention. Referring now to FIG. 1A, a substrate 100 is arranged and heated in a vacuum chamber 200. The pressure in the vacuum chamber 200 may be, for example, about 10⁻¹⁰ Torr, and the substrate 100 is heated at a high temperature by, for example, applying a direct current to the substrate 100. In heating the substrate 100, the surface of the substrate 100 is cleaned, and any oxide layer and/or other contaminants are eliminated. In one specific embodiment, the substrate 100 is heated to about 1300 degrees Celsius (° C.) for several minutes. The extent of absorption and the shape of the metallic material 300 adsorbed on the surface of the substrate 100 can be controlled using an ultra high vacuum reflection electron microscope (UHV-REM).

The extent to which the surface of the substrate 100 is cleaned can be monitored by using a reflection of high energy electron diffraction (RHEED) device. The RHEED device projects an electron beam onto the surface of the substrate 100 at a grazing angle using an electron gun, and thus forms a REM image from the beam reflected from the surface of the substrate 100. Thus, the crystal structure of the surface can be acquired. The substrate 100 is heated until it is determined that the surface has been cleaned sufficiently. After sufficient cleaning, the temperature of the substrate 100 can be regulated to a desired temperature.

As shown in FIG. 1A, a step 102 can be formed on the surface of the substrate 100 during the cleaning. In addition, a plurality of substrate elements 101 (e.g., atoms) are on the surface of the substrate.

Next, a metallic material 300 is injected into the vacuum chamber 200 and is adsorbed on the substrate 100 as shown in FIGS. 1B and 1C. The adsorption of the metallic material 300 can be carried out, for example, using vacuum evaporation. Specifically, the metallic material 300 is heated and evaporated within the vacuum chamber 200, and its vapor adsorbs to the surface of the substrate 100. Heating the metallic material 300 within the vacuum chamber 200 may comprise resistive heating or electron bombardment. Resistive heating comprises directly heating the metallic material 300 by flowing a current through the metallic material 300, which is placed on an evaporation source in the form of a thin film or line using a metal having a high melting point, such as tungsten (W), molybdenum (Mo), or tantalum (Ta). Alternatively, resistive heating comprises indirectly heating the metallic material 300 within a crucible furnace by winding a hot wire around the crucible furnace which is formed from high melting point oxides, such as Al₂O₃ or BeO. Electron bombardment comprises heating and evaporating the metallic material 300 by irradiating the metallic material 300 with an electron beam.

The metallic material 300 may comprise gold (Au), silver (Ag), tin (Sn), or the like. The adsorption rate of the metallic material 300 can be properly regulated by adjusting the heating temperature for the metallic material 300, the amount of the metallic material 300, the pressure in the vacuum chamber 200, and the like. In an exemplary embodiment, the metallic material 300 is adsorbed at the rate of 0.001 through 1.000 monolayers per minute.

In an exemplary embodiment, when adsorbing the metallic material 300, the temperature in the vacuum chamber 200 is about 20° C. to about 1350° C., and the pressure in the vacuum chamber 200 is about 10⁻⁶ to about 10⁻¹¹ Torr. In an exemplary embodiment, the adsorption rate of the metallic material 300 is about 0.001 to about 1.000 monolayers per minute, and the adsorption time is about 1 to about 1000 seconds (s).

In an exemplary embodiment, the metallic material 300 adsorbed on the surface of the substrate surface diffuses into the substrate 100, as shown in FIG. 1D. Owing to the diffusion, the metallic material 300 substitutes for an internal or bulk element of the substrate 100. The internal or bulk element 103 of the substrate 100 is rearranged or shifted to the surface of the substrate 100. The rearranged or shifted element 103 has substantially the same volume as the permeating metallic material 300. The shifted elements 103 of the substrate 100 can bind to each other, or with surface elements 101. Thus, nano-clusters can be formed as high as one atom on the surface of the substrate 100.

Referring now to FIG. 1E, the nano-clusters can rearrange or shift owing to the surface energy of the heated substrate 100, and bind with other clusters to form a 2D nanostructure 110.

At step 102, which has a higher surface energy than an adjacent area, the binding of the internal substrate elements 103 that have shifted to the surface, proceeds more actively. Accordingly, the 2D nanostructure 110b is formed along step 102 in the form of a wire.

In contrast, on a flat plane (i.e., without step 102), 2D nanostructures 110a and 110c comprise islands. The surface element 101 and the step 102 are formed in the cleaning stage and/or the substrate heating stage. The position, size, and/or shape of the 2D nanostructure may vary depending on the position, size, and/or shape of the surface element 101 and/or the step 102. Thus, it is possible to adjust the position, size, and/or shape of the 2D nanostructure 110 by checking the state of the surface of the substrate 100 using the REM image in the cleaning stage and regulating the element 101 and the step 102. Alternatively, the position, size, and/or shape of the 2D nanostructure 110 can be regulated by adjusting the heating temperature of the substrate 100, the amount of the metallic material 300 deposited, or the like.

Next, the motion of the nano-clusters on the surface of the substrate 100 is stopped by cooling the substrate 100. Thus, a stable 2D nanostructure 110 has been fabricated. The 2D nanostructure is formed using the same elements as the substrate 100. In this case, the 2D nanostructure 110 is fabricated as a monolayer or having the form of a wire or island.

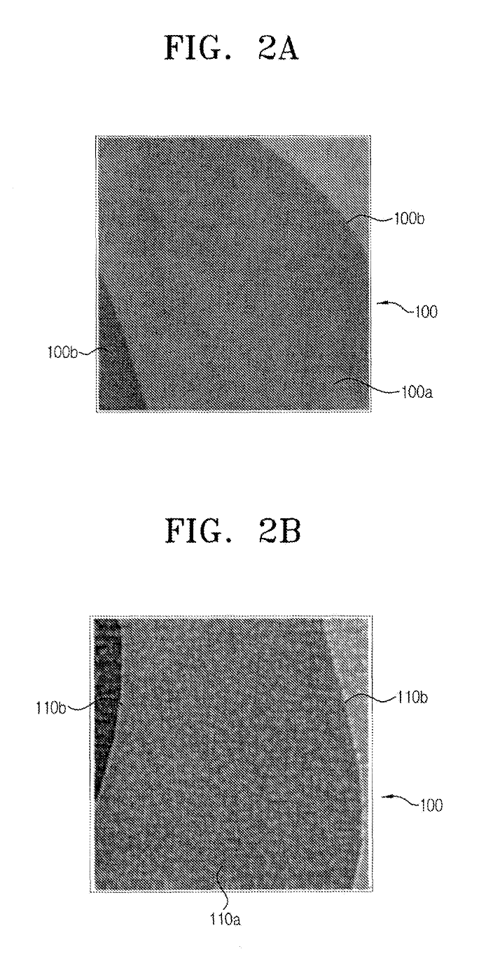

FIG. 2A illustrates the surface of a cleaned substrate 100, taken by an atomic force microscope (AFM). A step area 100b and a non-step area 100a are shown in the AFM image. The step area 100b is where the elements on the surface of the substrate 100 are arranged stepwise, whereas the non-step area 100a is where the surface of the substrate 100 is flat. In FIG. 2A, the substrate 100 is 5000×5000 square nanometers (nm²) ion size, and the height of a step 100b is about 0.31 nm² for a silicon substrate 110. The step area 100b is formed by a bunching phenomenon while the substrate 100 is heated at high temperature and cleaned in the vacuum chamber 200.

Still referring to FIG. 2A, the light areas are higher than the dark areas. According to a minute analysis of the AFM image, the average roughness of the non-step area 100a on the substrate 100 is less than about 0.01 Angstrom.

FIG. 2B is an AFM image, in which a 2D nanostructure has been fabricated by adsorbing the metallic material 300 on the cleaned substrate 100 of FIG. 2A. Specifically, gold of 0.15 ML has been adsorbed on the surface of the substrate at about 860° C. and cooled down at a rate of 400° C./s. In FIG. 2B, a great number of white dots 110 appear all over the non-step area 100a. Each dot represents a 2D nanostructure island. In contrast, white solid lines 110b appears along the step area 100b. The white solid line 110b represents a 2D nanowire. As described above, the size and the density of the 2D nanostructures 110a and 110b may vary according to the heating temperature of the substrate 100, the cooling rate, the amount of metallic material, the adsorption rate, or the like.

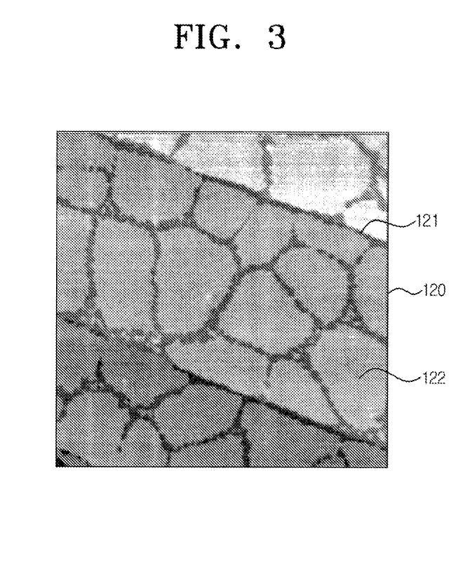

FIG. 3 is an AFM image of a 2D nanostructure fabricated in accordance with another exemplary embodiment. Specifically, gold of 0.42 ML has been adsorbed on the surface of the substrate 100 at 1070° C. and cooled down at a rate of 400° C./s. Large white specks 122 appear on non-step areas of the surface 120 of the substrate 100, having a step 121. Each speck 122 corresponds to a wide island shaped 2D nanostructure. The 2D nano-clusters formed on the step area 121 were absorbed to the white specks 122, that is, to the wide island shaped 2D nanostructures. Thus, the wire shaped 2D nanostructures were not formed.

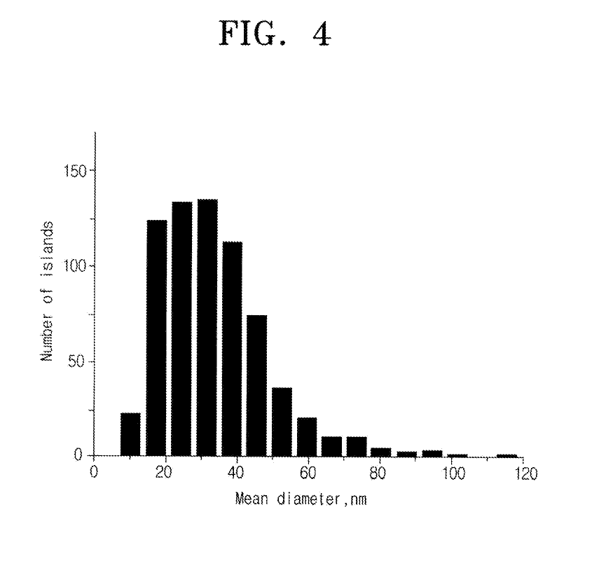

FIG. 4 graphically illustrates the size and the number of the 2D nanostructures in the AFM image of FIG. 2B. In FIG. 4, the horizontal axis indicates represents the mean diameter of the 2D nanostructures and the vertical axis represents the number of 2D nanostructures. As shown, the mean size of 2D nanostructure islands 110a is about 37 nm and the density is about 10¹⁰ per square centimeter (cm²).

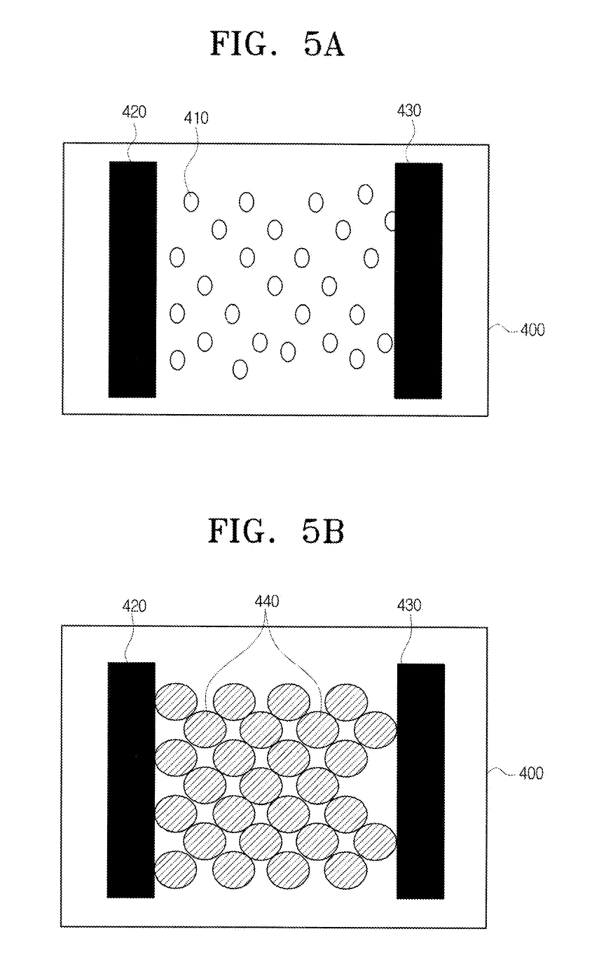

FIGS. 5A and 5B schematically illustrate exemplary applications for the 2D nanostructures fabricated according to the present invention. Specifically, FIGS. 5A and 5B show an electrode connecting chips using the 2D nanostructure. Referring first to FIG. 5A, the 2D nanostructure 410 is fabricated on the surface of the substrate 400. Next, chips 420 and 430 are accumulated. The chips 420 and 430 may be various circuit elements such as FBARs, filters, capacitors, and the like. Although FIG. 5A only illustrates island shaped 2D nanostructures 410, it is to be understood that the 2D nanostructure 410 can take various shapes including wires.

When a metallic material is deposited between the two chips 420 and 430 as shown in FIG. 5B, the metallic material agglomerates using the 2D nanostructure 410 as a core. Thus, a 3D nanostructure 440 including the 2D nanostructure 410 is fabricated. Since the 2D nanostructures 410 are uniformly distributed over the surface of the substrate 400, the size and the distribution of the 3D nanostructure 440 can also be uniform. Therefore, it is possible to minimize or prevent the fabrication of a 3D nanostructure having too large of a mass, and to fabricate a ultra thin film metallic electric wire as thick as one atom or several atoms.

In an exemplary embodiment, oxidation of the substrate can be controlled when the 2D nanostructure is fabricated by injecting the metallic material into the substrate. Specifically, when a silicon substrate is exposed to air, over time, its surface becomes oxidized. The extent of oxidization increases with time.

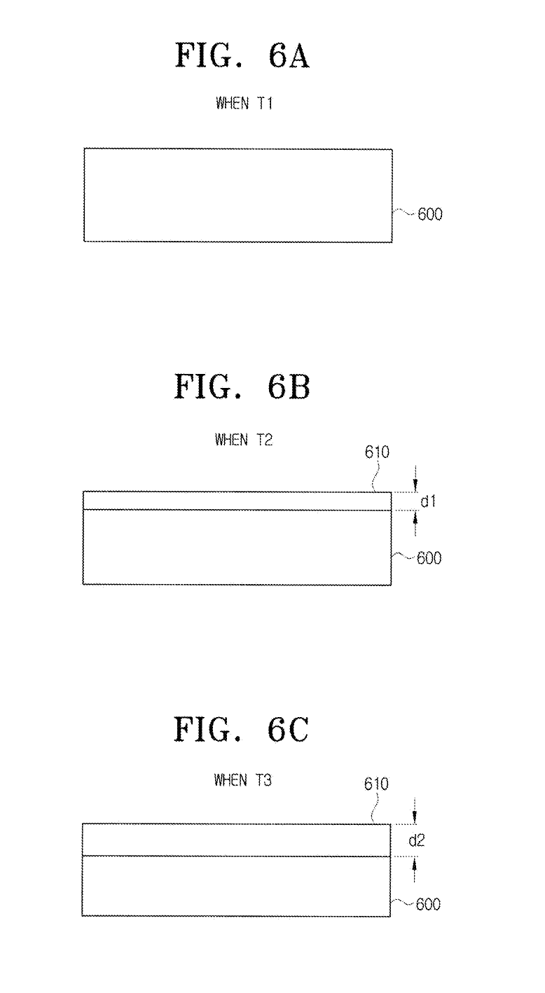

FIGS. 6A through 6C schematically illustrate oxidization of a conventional substrate 600 over time. FIGS. 6A through 6C show the oxidization at t1, t2, and t3 (wherein t1<t2<t3), respectively. Although the original state of the substrate 600 is maintained at t1 as shown in FIG. 6A, an oxide layer 610 is formed as time elapses as shown in FIGS. 6B and 6C. The thickness of the oxide layer 610 is d1 at t2 and becomes d2 (wherein d2>d1) at t3.

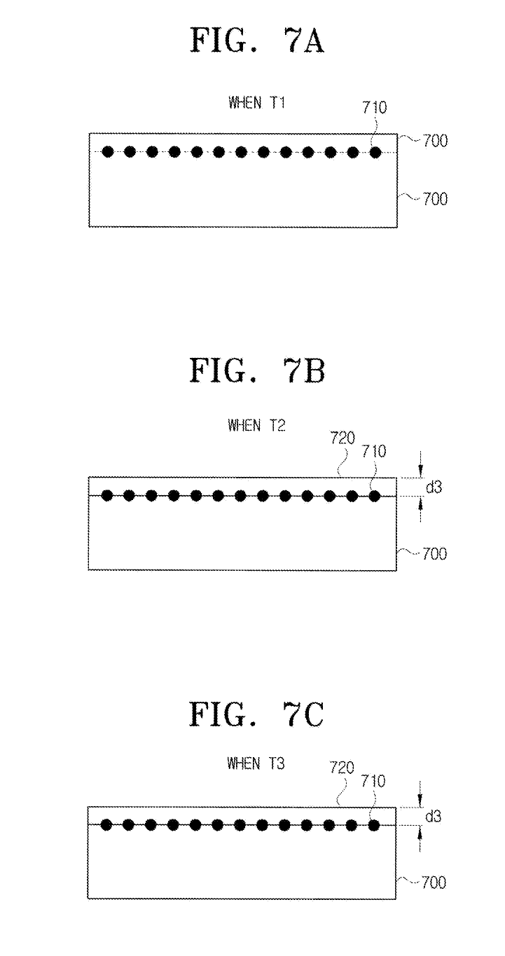

In contrast, FIGS. 7A through 7C schematically illustrate oxidization of a substrate 700 on which a 2D nanostructure 710 is fabricated according to an exemplary embodiment of the present invention over time. Specifically, FIGS. 7A through 7C show the oxidization at t1, t2, and t3 (wherein t1<t2<t3), respectively. In FIG. 7A, a metallic material 710 permeates into the substrate 700. The permeation depth varies according to characteristics of the metallic material 710. At t1, the surface of the substrate 700 maintains its original state without oxidization as shown in FIG. 7A. As time passes, an oxide layer 720 is formed as shown in FIGS. 7B and 7C. The thickness d3 of the oxide layer 720 is restricted to the area where the metallic material 710 is present. In other words, the metallic material 710 prevents further oxidization of the substrate 700, as time progresses from t2 to t3. As such, the adsorption of the metallic material 710 can regulate the extent of oxidization.

As described above, the 2D nanostructures can be fabricated as thick as a single atom, without using any separate external sources. Therefore, the time and cost required to fabricate the 2D nanostructures can be reduced. Furthermore, delicate and complicated nanostructures can be fabricated because the size and the shape of the nanostructures are controllable.

Although the present invention has been described herein with reference to exemplary embodiments, these exemplary embodiments do not serve to limit the scope of the present invention. Accordingly, those skilled in the art to which the present invention pertains will appreciate that various modifications are possible, without departing from the scope and spirit of the invention as disclosed in the appended claims. Accordingly, such modifications and variations are intended to come within the scope of the appended claims.

What is claimed is:

1. A method of fabricating a two dimensional nanostructure, comprising:
heating a substrate within a vacuum chamber;
injecting a metallic material into the vacuum chamber;
adsorbing the metallic material on a surface of the substrate; and
cooling the substrate to fabricate the two dimensional nanostructure on the surface of the substrate.

2. The method as in claim 1, further comprising:
diffusing the metallic material into the substrate;
substituting the diffused metallic material for an internal element of the substrate, wherein the internal element has substantially the same volume as the diffused metallic material; and
shifting the internal element to the surface of the substrate.

3. The method as in claim 2, wherein the shifted internal element, binds to the surface of the substrate during the cooling.

4. The method as in claim 1, wherein a step is formed on the surface of the substrate during the heating.

5. The method as in claim 1, wherein the two dimensional nanostructure comprises a wire shaped two dimensional nanostructure fabricated along the step or an island shaped two dimensional nanostructure fabricated on a non-step area of the surface of the substrate.

6. The method as in claim 1, wherein the substrate is a crystalline silicon substrate.

7. The method as in claim 1, wherein the metallic material is at least one of gold, silver, and tin.

8. The method as in claim 1, wherein a temperature in the vacuum chamber is about 20 degrees Celsius to about 1350 degrees Celsius.

9. The method as in claim 1, wherein the metallic material is adsorbed on the surface of the substrate at about 0.001 to about 1.000 monolayers per minute.

10. The method as in claim 1, wherein the metallic material is adsorbed on the surface of the substrate for about 1 second to about 1000 seconds.

11. The method as in claim 1, wherein a pressure in the vacuum chamber is about 10⁻⁶ Torr to about 10⁻¹¹ Torr.

12. The method as in claim 1, wherein a size of the two dimensional nanostructure is about 10 nanometers to about 1300 nanometers, and a surface density of the two dimensional nanostructure is greater than about 10¹⁰ per square centimeters.

13. A two dimensional nanostructure fabricated on a surface of a substrate according to the method of claim 1.

14. The two dimensional nanostructure of claim 13, wherein the surface of the substrate comprises a step.

15. The two dimensional nanostructure of claim 13, wherein the two dimensional nanostructure comprises a wire shaped two dimensional nanostructure fabricated along the step, or an island shaped two dimensional nanostructure fabricated on a non-step area of the surface of the substrate.

16. The two dimensional nanostructure of claim 13, wherein the substrate is a crystalline silicon substrate.
